(19) United States
(12) Patent Application Publication
(10) Pub. No.: US 2015/0264829 A1
(43) Pub. Date: Sep. 17, 2015

(54) Electronic Assembly with a Housing Having a Plastic Part and a Metal Part

(71) Applicant: Continental Automotive GmbH, Hannover (DE)

(72) Inventor: Markus CHRISTOPH, Regensburg (DE)

(21) Appl. No.: 14/724,237

(22) Filed: May 28, 2015

Related U.S. Application Data
(63) Continuation-in-part of application No. PCT/DE2014/200600, filed on Oct. 28, 2014.

(30) Foreign Application Priority Data
Nov. 29, 2013 (DE) 10 2013 224 588

(51) Int. Cl. H05K 5/02; H05K 1/02; H05K 5/03; H05K 5/04; H05K 5/00

(52) U.S. Cl. CPC H05K 5/0247; H05K 5/0217; H05K 5/04; H05K 5/006; H05K 5/03; H05K 1/0215; H05K 5/0004

(57) ABSTRACT

An electronic assembly includes a housing with a plastic part and a metal part. The plastic part includes a mounting lug that mechanically mounts the housing on an external metal support structure. The metal part includes a metal lid and a grounding tab aligned with, or received in a recess of, the mounting lug. Electronic components are grounded onto the metal lid inside the housing, and the grounding tab is electrically connected to the support structure. To isolate mechanical forces and vibrations from the metal lid, a transition part of the grounding tab has a reduced width and/or thickness, and/or includes a bend. The metal lid is received in a recess of the plastic part and is surrounded by a plastic perimeter wall thereof. The plastic part carries the mechanical forces and vibrations, which are substantially isolated from the metal lid. The metal part provides grounding and closes the housing.

### CROSS-REFERENCE TO RELATED APPLICATIONS

This application is a Continuation-In-Part (CIP) under 35 USC 111(a) and 120 of PCT International Application PCT/DE2014/200600 filed on Oct. 28, 2014. Through the PCT application, the present application also claims priority under 35 USC 119 of German Patent Application DE 10 2013 224 588 filed on Nov. 29, 2013. The entire disclosures of the priority application and the PCT application are incorporated herein by reference.

### FIELD OF THE INVENTION

The invention relates to an electronic assembly with a housing having a plastic part and a metal part, which together enclose an interior space of the housing, in which at least one electronic component is arranged, for example on a circuit board. The housing has a mounting flange or mounting lug by which the electronic assembly is mechanically mounted on an external support structure.

### BACKGROUND INFORMATION

Known electronic assemblies comprise a housing that is typically a two-part housing including a main housing body or container that bounds an inner space therein, and a lid or cover that closes at least one side of the main housing body or container. Thus, electronic components arranged in the inner space of the housing are preferably entirely surrounded and enclosed by the housing, which is preferably also sealed, in order to protect the electronic components from the outside environment (e.g. water, moisture, dust, etc.). Such housed electronic assemblies are especially known, for example, in the field of automobile electronics, where the housing protects the electronic components from the harsh operating environment within the engine compartment of the automobile, for example. In order to reduce the weight, the manufacturing cost, and the assembly and installation cost, it is becoming increasingly common to use housings that comprise a plastic part, e.g. a main housing body or container made of plastic, and a metal part, e.g. a metal lid or cover for the plastic housing part.

It is further known to provide an electrical ground connection for such an electronic assembly via a metal insert part that is injection molded in the plastic material of the plastic housing, for example as disclosed in German Patent Publication DE 197 42 458 A1. The metal insert part is provided on a mounting flange or lug and is secured on a metal carrier or support structure via mechanical fastener or connection means. Furthermore, the metal insert part has an electrical connection into the interior of the housing and is there connected with a ground contact on the circuit board of the electrical components. However, the manufacturing of such a housing with a metal insert part injection-molded into the plastic material of the housing is expensive and complicated.

The German Utility Model Publication DE 201 12 595 U1 discloses an electrical ground connection via metallic bushings in the mounting flange of a housing, in which the circuit board of the electronic assembly extends outwardly into the mounting flange and there contacts the metal bushings. However, due to the high forces that arise in the mounting flange during the mounting (e.g. screwing or bolting) thereof onto a support structure, or during the driving operation of the motor vehicle in which the electronic assembly is installed, there is the danger that these high forces are transmitted directly into the circuit board at the location of the mounting flange, and the circuit board may thereby be damaged.

It is also known to provide a metal adapter plate for securing a housing in a motor vehicle, for example as disclosed in German Patent Publication DE 10 2009 045 565 A1. In that known arrangement, the mounting flange or mounting lug is formed directly on this adapter plate itself. Therefore, the adapter plate must have a considerable thickness in order to have sufficient strength to take up and withstand the arising mechanical forces of the mounting flange.

The US Patent Application Publications US 2011/0170269 A1 and US 2012/0261409 A1 disclose electronic assembly housings as well as suitable manufacturing methods, in which lugs extend from the metal lid into the mounting flange of the plastic housing. The metal lid including the protruding lugs thereof are constructed and formed to provide structural support and carry mechanical loads. As a result, mechanical vibrations, for example as arise in a motor vehicle especially when driving on uneven or bumpy streets, are transmitted through the mounting points via the metal lid directly to the circuit board, where the transmitted mechanical forces and vibrations disadvantageously load or even entirely destroy solder connections, electronic components, sensors or the like on the circuit board.

### SUMMARY OF THE INVENTION

In view of the above, it is an object of an embodiment of the invention to provide an improved electronic assembly with a housing that provides an electrical ground connection, substantially protects or isolates the circuit board and electronic components mounted thereon from mechanical forces or vibrations that arise at the mounting points, and that can be produced, assembled and installed simply and economically. The invention further aims to avoid or overcome the disadvantages of the prior art, and to achieve additional advantages, as apparent from the present specification. The attainment of these objects is, however, not a required limitation of the claimed invention. The above objects can be achieved in an electronic assembly and/or a housing for an electronic assembly according to an embodiment of the invention. For example, such an electronic assembly comprises a housing and electronic components mounted therein. The housing comprises a plastic part, for example including a main plastic housing body or container, and a metal part, for example including a metal cover or lid. Together, the plastic part and the metal part substantially, and preferably completely, enclose the electronic components within an interior space of the housing. The plastic part further has at least one mounting flange or mounting lug by which the electronic assembly is mechanically mounted on an external metal support structure, such as a metal support bracket or a metal component of a motor vehicle frame, body, engine, etc. (alternatively and equivalently, the support structure need not consist of metal, but may be made of plastic, composite material, ceramic, etc. with a metalized surface layer or a metal conductor thereon). The metal part further includes at least one grounding tab that protrudes from a main body or lid of the metal part. The grounding tab is configured and arranged generally along or aligned with or in registration with the mounting flange or mounting lug of the plastic housing part. Within the housing, the metal lid is electrically connected to a ground contact of one or more electronic components of the assembly, and outside of the housing the grounding tab is contacted and electrically connected with the metal support structure, between the mounting flange or lug and the support structure.

In further preferred embodiments, the metal part is purposely configured and arranged so as to substantially isolate mechanical forces and vibrations between the mounting points and the circuit board or electronic components within the housing. Preferably, the metal part provides no (or no significant) mechanical structural support for the circuit board or the electronic components within the housing, or for mounting the assembly on the external structural support. Instead, such mechanical and structural support is provided only (or substantially only) by the plastic housing part. Each grounding tab includes a connection portion in alignment or registration with the mounting portion of a mounting lug of the plastic part, and a transition portion or neck that extends from the connection portion to the main body or lid portion of the metal part. The connection portion establishes the electrical grounding connection to the support structure. The transition portion or neck serves as an electrical grounding path, and serves to isolate external mechanical forces or vibrations from the main body or lid portion of the metal part and the electronic components contained in the housing. In this regard, respective embodiments of the assembly according to the invention have at least one force or vibration isolating feature as follows.

For this purpose, the transition portion may have a narrower width than the connection portion of the grounding tab, and/or the transition portion may have a thinner thickness than the connection portion of the grounding tab or than the main lid portion of the metal housing part, and/or the transition portion may have a thickness of at most 2 mm, and/or the transition portion may include a bent portion with at least one bend or deflection adjoining the main portion of the metal part or adjoining the connection portion. The bent portion has at least one or preferably two or more bends or deflections out of a plane on which the transition portion and/or connection portion lie. The bent portion may thus have a serpentine or zig-zag or Z-shaped or U-shaped configuration with at least two or more deflections or bends. The transition portion having a narrower and/or thinner configuration than the connection portion may form a predetermined bending location or even a predetermined breaking location to protect the assembly from the transmission of excessive mechanical forces or vibrations. Any individual one of the above special features of the grounding tab can be included individually in a respective single embodiment, or can be combined in an embodiment that has two or more or all of these features. Each one of these features serves to isolate and minimize the transmission of mechanical forces and vibrations from the connection portion of the grounding tab to the main body or lid panel of the metal part. Thereby, the transmission of mechanical forces and vibrations to the electronic components within the housing is minimized.

Another feature by which the metal part does not provide significant mechanical structural support, and instead isolates and reduces the transmission of mechanical forces and vibrations, is that the overall metal part is very thin, for example having a maximum thickness no more than 2 mm thick, preferably no more than or less than 1 mm thick, and more preferably from 0.5 mm to 0.6 mm thick. Such a very thin metal part is too thin to provide mechanical structural support, and instead is easily elastically bendable or deflectable so as to prevent or isolate the transmission of mechanical forces and vibrations. Because the metal part is very thin and thus not very robust or sturdy, it may be further reinforced and protected in further embodiments. Namely, in one embodiment, the main body portion or lid panel of the metal part is stiffened by embossed or press-molded stiffening ribs, simply to provide the lid panel with sufficient stiffness to support itself in a flat planar condition. In another embodiment, the connection portion and optionally the transition portion of each grounding tab of the metal part is recessed in a correspondingly shaped recess of the associated mounting lug of the plastic housing part, such that all edges of the metal grounding tab are surrounded and covered by a plastic perimeter wall of the plastic part. The main body portion or lid panel of the metal part may similarly be received in a recess of the plastic housing part, whereby the perimeter edges of the metal lid panel are also surrounded by a plastic perimeter rim wall of the plastic housing. Thereby, the thin metal part, and especially the thin grounding tab thereof, is protected against mechanical damage before and during mounting thereof. Once mounted, the metal part is completely covered and enclosed by the plastic part. These embodiment features can be combined with one another, or included individually in respective embodiments, and/or combined with any one or more of the force-isolating features mentioned above.

Embodiments of the invention thus provide an advantageous combination of several features. The metal part and the plastic part of the housing together surround and enclose the interior space of the housing, in which the electronic components are housed and preferably entirely surrounded and enclosed, most preferably in a sealed manner. Furthermore, the plastic part mounts the housing on an external support structure, while the metal part of the housing provides an electrical ground connection for the electronic components to the support structure on which the electronic assembly is mounted. To establish the electrical connection of the grounding tab with the metal support structure, the grounding tab is received and clampingly held between the mounting lug of the plastic housing part and the metal support structure, or between the mounting lug and the fastener or securing means by which the assembly is secured to the support structure. Thereby, the need for a separate additional insert part (e.g. a metal part that is inserted and injection molded in the plastic housing part) is avoided. Furthermore, the metal part is configured and constructed so that the grounding tab or tabs thereof are substantially mechanically de-coupled from the rest of the housing so as to isolate or minimize the transmission of mechanical forces and vibrations from the mounting locations into the main portion of the metal housing part. This is achieved, as mentioned above, by any one or more of the following features: a reduced width of the transition portion relative to the connection portion of the grounding tab, a reduced thickness of the transition portion relative to the connection portion of the grounding tab, a thickness of the transition portion of not more than 2 mm, and/or a bent portion having one or more bends or deflections out of a plane of the connection portion or transition portion of the grounding tab.

The mechanical mounting forces and any arising vibrations are supported by the plastic housing part, and particularly by the mounting flange or mounting lugs of the plastic housing part mechanically secured to the support structure, for example a mounting bracket or other rigid part of a motor vehicle. Because the metal part does not need to withstand any significant mechanical loading, it may be made of a rather thin sheet metal, e.g. of at most 2 mm thickness. Thereby the metal part is lighter in weight and more economical to produce.

To further protect the metal part, e.g. the metal lid, of the housing from mechanical forces and influences, the entire metal part is preferably recessed or set into a corresponding recess in the plastic part of the housing, and preferably entirely circumferentially surrounded or enclosed by a perimeter rim or wall of plastic housing material.

### BRIEF DESCRIPTION OF THE DRAWINGS

In order that the invention may be clearly understood, it will now be explained in further detail, in connection with example embodiments thereof, with reference to the accompanying drawings, wherein:

FIG. 1 is a perspective overview of an embodiment of an electronic assembly according to the invention, in an assembled condition, showing especially the metal lid or cover on the plastic body of the housing;

FIG. 2 is a sectional view of a portion of the assembly at a mounting location thereof;

FIG. 3 is a perspective view of the metal housing part by itself, as seen from the interior side of the housing;

FIG. 4 is a perspective view of a detail portion of the metal housing part from the exterior side of the housing;

FIG. 5A is a plan view of the metal housing part;

FIG. 5B is a sectional view of the metal housing part along the section line VB-VB shown in FIG. 5A; and

FIG. 6 is a perspective view of a circuit board installed in the plastic housing part, before installation of the metal housing part.

### DETAILED DESCRIPTION OF PREFERRED EXAMPLE EMBODIMENTS AND THE BEST MODE OF THE INVENTION

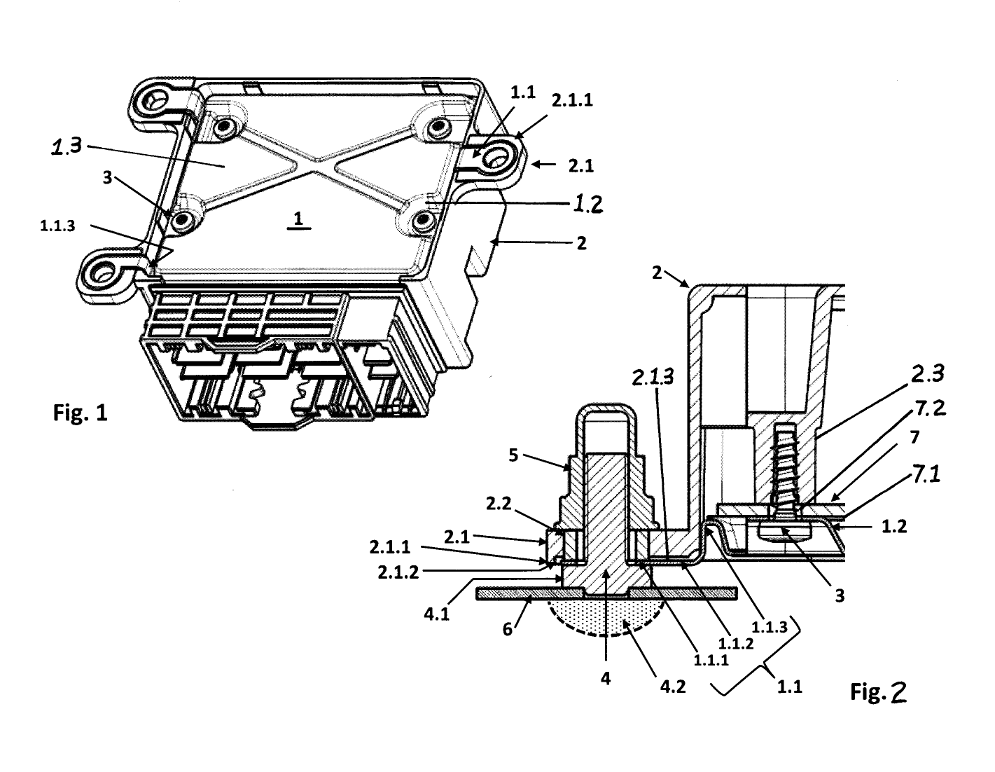

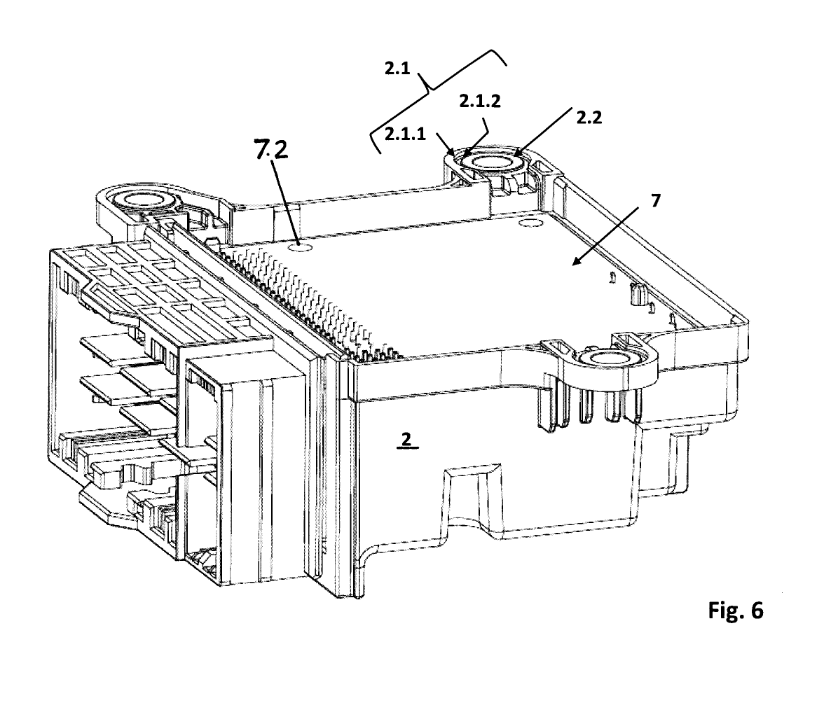

FIG. 1 shows an embodiment of an electronic assembly according to the invention, including a plastic part 2 forming a plastic main part or plastic container of the housing, and a metal part 1 forming a metal cover or lid of the housing. The plastic part 2 and the metal part 1 together bound and enclose an interior space within the housing, in which electronic components are mounted, for example on a circuit board 7. The housing preferably entirely encloses the electronic components in the housing's interior space. The housing may include an electrical plug connector (unnumbered, but shown in FIGS. 1 and 6), which may either be integrated as one-piece in the plastic part 2 or as an additional plastic part connected to or inserted in the plastic housing part 2. The metal part 1 actually forms a portion of the enclosure of the housing and is not merely a metal insert part that is inserted or injection molded into the plastic housing. Thus, the metal part 1 actually serves a housing function. In the present example embodiment, the housing has a six-sided parallelepiped shape, with the plastic part 2 bounding five sides and the metal part 1 closing the final sixth side of the interior space of the housing.

For mounting the housing on an external support structure 6 (see FIG. 2), such as a support bracket or other rigid metal or metalized or otherwise conductive part of a motor vehicle, the plastic part 2 additionally includes a mounting flange that is embodied as three individual mounting lugs 2.1 that protrude outwardly from the main plastic body or housing container of the plastic part 2. Alternatively, the plastic housing part may include a continuous perimeter mounting flange, or one or more individual mounting lugs.

The metal part 1 of the housing is configured as a metal cover or lid in the present embodiment, and includes a main body or lid panel 1.3 and at least one, but in the present embodiment three, grounding tabs 1.1 protruding laterally outwardly from the lid panel 1.3 of the metal cover 1. Preferably, the entire plastic part 2, including the main body or container of the plastic housing and the mounting lugs 2.1, is integrally formed as a one-piece component of plastic, for example by injection molding. Similarly, the metal part 1 including the main body or lid panel 1.3 as well as the grounding tabs 1.1, is formed as a single one-piece metal component of thin sheet metal, for example by stamp-cutting and stamp-forming or drawing.

The grounding tabs 1.1 are generally aligned or in registration with the mounting lugs 2.1 of the plastic housing part 2, and arranged thereunder, so that in the mounted state, these grounding tabs 1.1 are received between the mounting lugs 2.1 and the metal support structure 6. Thereby, when the mounting lugs 2.1 are mechanically secured to the support structure 6, the grounding tabs 1.1 become electrically conductively connected to the support structure 6 without requiring additional steps or efforts for grounding.

A mounting location of the electronic assembly in the mounted or installed arrangement is shown in detail in an enlarged sectional view in FIG. 2. As mentioned above, FIG. 2 especially shows a grounding tab 1.1 clampingly held between the mounting lug 2.1 and the metal support structure 6, whereby the plastic housing part 2 is mechanically secured to the support structure 6, and the metal housing part 1 is electrically conductively connected to the support structure 6. More particularly, in the present example embodiment, a mounting sleeve 2.2 is preferably inserted in a mounting hole of the mounting lug 2.1 of the plastic part 2. This mounting sleeve 2.2 may be made of metal and is harder or stronger than the plastic material of the mounting lug 2.1. The mounting sleeve 2.2 thus ensures that the plastic mounting lug 2.1 will not be crushed or deformed when the fastener or securing means 4, 5 is tightened. The mounting sleeve 2.2 further ensures that the assembly will remain stably mounted and supported throughout the operating lifetime of the product. While the mounting sleeve 2.2 may be made of metal, it does not serve any significant function or purpose as an electrical conductor for the grounding connection. Instead, the grounding connection may be provided by directly contacting the grounding tab 1.1 onto the metal support structure 6. Alternatively, in the illustrated embodiment, the fastener 4, such as a threaded bolt or welding stud or rivet, includes a stand-off collar 4.1 between the grounding tab 1.1 and the support structure 6. Thereby, the electrical grounding connection is achieved from the grounding tab 1.1 through the metal stand-off collar 4.1 of the fastener 4 to the metal support structure 6. When a bolt is used as the fastener 4, the threaded shaft of the bolt 4 extends through a hole in the grounding tab 1.1, in registration with the hole of the mounting lug 2.1 of the plastic housing part 2. A cap nut 5 on the opposite (e.g. upper) side of the plastic mounting lug 2.1 secures the bolt 4, while a bolt head 4.2 bears against the opposite (e.g. lower) surface of the metal support structure 6. As an alternative, instead of the bolt 4 and cap nut 5, the assembly may be mounted by a spot weld at each mounting location, for example via a welding stud or rivet 4 with a welded head 4.2.

The mounting sleeve 2.2 as shown in FIG. 2 may be dimensioned slightly longer than the thickness of the portion of the plastic mounting lug 2.1 in which the sleeve 2.2 is received. Thereby, the mounting sleeve 2.2 tightly presses the grounding tab 1.1 against the stand-off collar 4.1 and/or the support structure 6, and optionally also forms a slight gap space 2.1.3 between the plastic mounting lug 2.1 and the metal grounding tab 1.1. Furthermore, the mounting sleeve 2.2 may be secured to the plastic mounting lug 2.1, either by being injection molded therewith, or screwed or expanded or otherwise mechanically secured into the hole in the mounting lug 2.1. Thereby, and through the secure fastening between the cap nut 5 and the stand-off color 4.1 and/or the support structure 6, the plastic mounting lug 2.1 is securely mechanically fastened to the support structure 6 and thereby takes-up and transmits mechanical forces and vibrations from the housing through the fastener 4 into the support structure 6 and vice versa. However, the gap space 2.1.3 helps to isolate at least a transition portion 1.1.2 of the metal grounding tab 1.1 from the plastic mounting lug 2.1.

The mounting arrangement shown in FIG. 2 provides a secure, fixed mechanical fastening and support of the plastic mounting lug 2.1 onto the support structure 6, as well as an electrical grounding connection of the metal grounding tab 1.1 onto the support structure 6. Embodiments of the assembly according to the invention further include features to isolate, avoid or reduce the transmission of mechanical forces and vibrations from the mounting location to the rest of the metal housing part 1, as follows.

Namely, embodiments of the invention aim to isolate or reduce the transmission of mechanical forces and vibrations into the metal housing part 1, so that the metal housing part 1 can be made weaker, and thereby thinner and lighter, and thus more economically, while also protecting against vibrations, the electronic components contacted on the metal part 1 inside the housing, and while still providing an electrical grounding connection to the external support structure 6. As shown in FIGS. 1 and 2, the main body part or lid panel 1.3 of the metal cover 1 has depressions 1.2, and inside the housing a circuit board 7 carrying electronic circuit components (not shown) is mounted between the depressions 1.2 of the metal part 1 and internal plastic projections 2.3 of the plastic housing part 2. A metalized circuit trace and especially a ground circuit trace 7.1 of the circuit board 7 is directly electrically connected by direct contact with the depression 1.2 of the metal part 1. Thereby, the metal part 1 provides the grounding connection from the circuit board 7 to the external metal support structure 6. Furthermore, the metal housing part 1 is secured to the plastic housing part 2 by fasteners such as self-tapping screws 3 extending through holes in the depressions 1.2 of the metal housing part, and through holes 7.2 in the circuit board 7, and then screwed into blind receiving holes in the plastic projections 2.3 of the plastic housing part 2. Thereby, the circuit board 7 is also securely mechanically fastened onto the plastic projections 2.3 of the plastic housing part 2.

While it is sufficient that only one of the depressions 1.2 of the metal part 1 makes electrical contact with a ground conductor 7.1 of the circuit board 7, and only a single grounding tab 1.1 is provided to establish the electrical grounding connection to the support structure 6, it can be preferred to provide plural depressions 1.2 making electrical grounding contact with the circuit board 7, and plural grounding tabs 1.1. This arrangement provides redundancy in the electrical grounding connection, and/or permits variable mounting configurations in which at least only one of the available plural grounding tabs 1.1 must be secured to a grounded/metal support structure, while the other mounting tabs and mounting lugs may be secured to ungrounded support members.

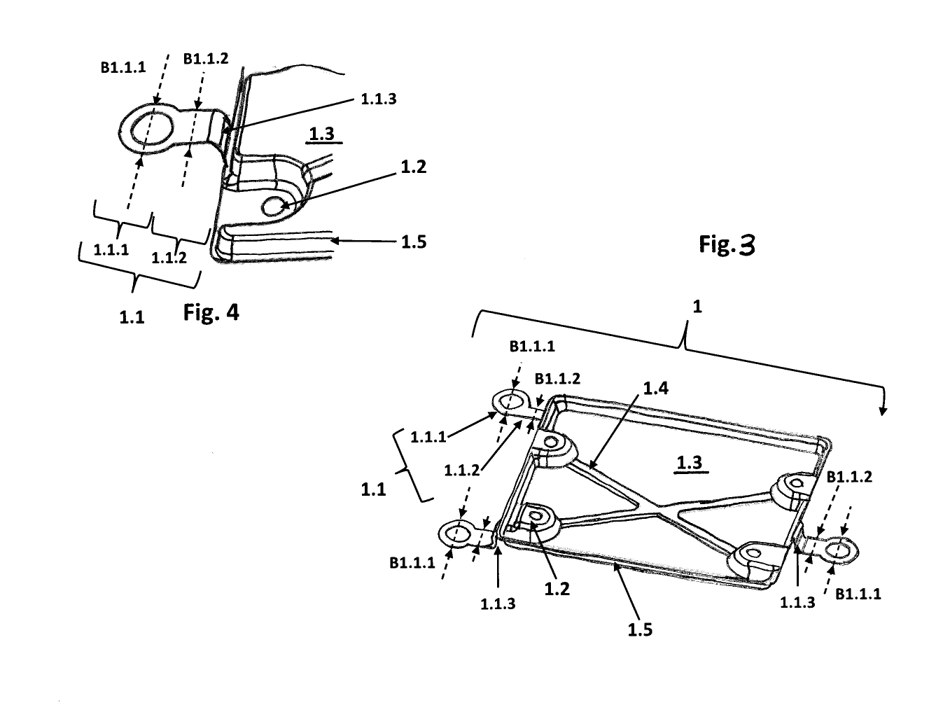

The metal part 1 is preferably formed from sheet metal with a thickness of at most 2 mm, preferably not more than 1 mm or even less than 1 mm, and especially preferably from 0.5 mm to 0.6 mm. The metal part 1 can be formed by stamp-cutting and stamp-forming or drawing the sheet metal to form the contoured shape of the part including the depressions 1.2, the special configuration of the grounding tabs 1.1, as well as stamped or embossed stiffening ribs 1.4 that stiffen the main body or lid panel 1.3 of the metal part 1 to be self-supporting. Thereby, the entire metal part 1 is embodied as a single one-piece component of sheet metal as is shown and will be described in further detail with reference to FIGS. 3, 4, 5A and 5B.

As can be seen in FIGS. 1 to 4, 5a and 5B, each grounding tab 1.1 includes a connection portion 1.1.1 that establishes the electrical connection to the support structure 6 at the distal free end of the grounding tab 1.1, and a transition portion or neck 1.1.2 that connects the connection portion 1.1.1 to the main body 1.3 of the metal part. The connection portion 1.1.1. has a hole in alignment or registration with the hole of a respective mounting lug 2.1 of the plastic housing part 2, through which the mounting fastener 4 is received (as described above in connection with FIG. 2). The width B1.1.1 (see FIGS. 3, 4 and 5A) is generally dictated by the required width or diameter of the mounting fastener 4. In other words, the hole in the connection portion 1.1.1 has the appropriate diameter for receiving the mounting fastener 4 of suitable size, and the width B1.1.1 is sufficiently larger than the diameter of the hole therein to avoid tearing or breaking of the metal grounding tab 1.1 at this location. However, the transition portion or neck 1.1.2 has a width B1.1.2 that is smaller than the width B1.1.1 of the connection portion 1.1.1. In other words, the transition portion 1.1.2 is narrower than the connection portion 1.1.1, when considered in the plane of the connection portion or transition portion, in a width direction generally along the adjoining edge of the main body 1.3 of the metal part 1, or in a direction generally transverse to the longitudinal extension direction of the grounding tab protruding away from the main body 1.3 of the metal part 1. The narrower width of the transition portion 1.1.2 can be a consistent width along the entire transition portion, or can be provided by notches or cut-outs at the edges of the transition portion. Additionally or alternatively, the transition portion 1.1.2 may be thinner than, i.e. have a thickness less than, the connection portion 1.1.1 or the main body 1.3. This can be achieved, for example, by providing a groove or score line extending across the transition portion, or pressing/drawing the transition portion 1.1.2 to a reduced thickness compared to the connection portion 1.1.1 or the main body 1.3. Also, the transition portion will not transmit significant mechanical forces or vibrations if it is preferably formed from sheet metal with a thickness of at most 2 mm, preferably not more than 1 mm or even less than 1 mm, and especially preferably from 0.5 mm to 0.6 mm, like the main body 1.3 or thinner than the main body 1.3.

The reduced width and/or thickness of the transition portion may form a predetermined bending location or even a predetermined breaking location of the grounding tab, which will bend or break if the grounding tab is exposed to excessive forces or vibrations, thereby preventing such excessive forces or vibrations from being transmitted to the main body 1.3.

Particularly, for example, the transition portion 1.1.2 may have a width B1.1.2 that is at most 80%, or preferably at most 75%, or more preferably at most 70%, or at most 65%, or at most 60%, or at most 50% of the width B1.1.1 of the connection portion 1.1.1. The transition portion 1.1.2 may have a thickness, for example, that is no more than 80% or no more than 75% of the thickness of the connection portion 1.1.1 or of the main body 1.3. The entire grounding tab 1.1 or only the transition portion 1.1.2 may be thinner than the main body 1.3

Furthermore, alternatively or additionally, the transition portion 1.1.2 may comprise a bent portion 1.1.3 having at least one bend or deflection, or preferably at least two bends or deflections, out of a plane of the connection portion 1.1.1 or of a main part of the transition portion 1.1.2. Each one of these features (reduced width, reduced thickness, or at least one bend), or any combination of one or more or all of these features, serve to de-couple the connection portion 1.1.1 from the main body 1.3 of the metal part 1 with respect to the transmission of mechanical forces and/or vibrations.

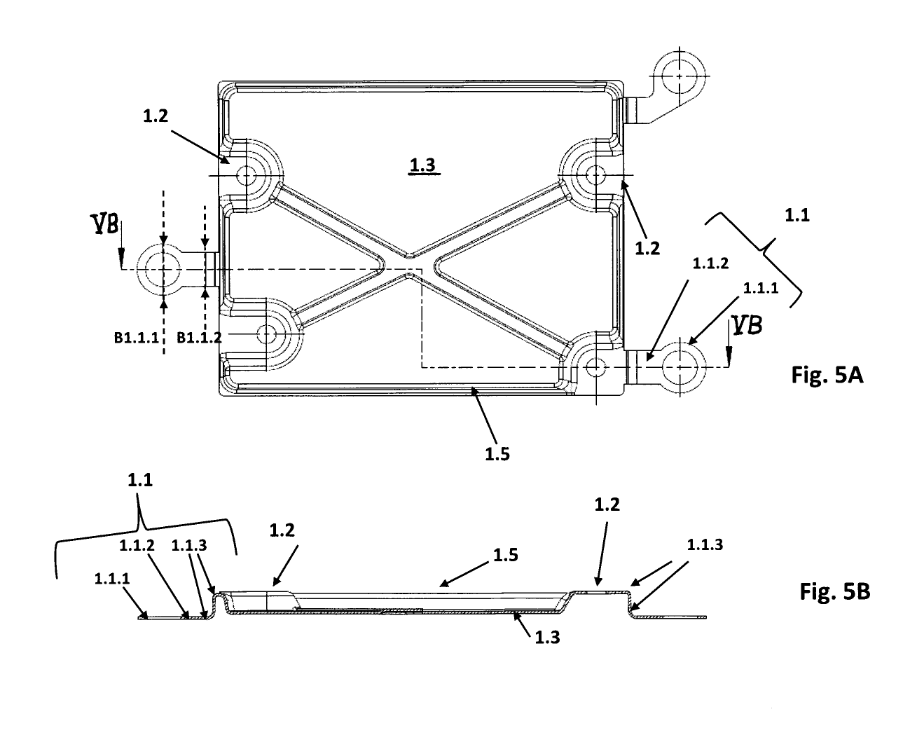

While the bent portion includes at least one bend or deflection 1.1.3 in the transition portion 1.1.2 of the grounding tab 1.1, it preferably includes at least two bends or deflections, thereby forming a Z-shaped, or U-shaped, or zig-zag or serpentine configuration (for example in a sectional side view as shown in FIGS. 2 and 5B) of the transition portion 1.1.2 adjoining the main body 1.3 of the metal part 1. With this configuration, the grounding tab 1.1 and especially the transition portion 1.1.2 with the bent portion 1.1.3 thereof has a certain defined vibrational elasticity and elastic flexibility, which ensures that mechanical forces and vibrations are not transmitted, or only slightly transmitted in a reduced or damped manner, from the connection portion 1.1.1 to the main body 1.3 of the metal part 1. Thereby, the mechanical forces and vibrations arising at the mounting location will not be significantly conducted through the metal part 1 directly to the circuit board 7 arranged on the main body 1.3 (depressions 1.2) inside the housing. This helps to protect the electronic components, solder connections, and the like on the circuit board 7 from damage that can be caused by such vibrations and mechanical forces.

By providing a feature wherein the transition portion has a reduced width compared to the connection portion, and/or the transition portion has at least one out-of-plane bend, thereby the reduced width and/or the bend serve to reduce a strength or stiffness of the grounding tab relative to a condition without such a reduced width (e.g. a comparative grounding tab having a transition portion and connection portion with the same uniform width) and/or without such a bend (e.g. a comparative grounding tab having a flat planar configuration). This helps to ensure that no significant or no substantial mechanical forces and/or vibrations are transmitted through the transition portion 1.1.2 into the main body or lid 1.3

The feature that no significant or no substantial mechanical forces and/or vibrations are transmitted through the transition portion 1.1.2 into the main body or lid 1.3, may mean that the plastic housing 2 and particularly the plastic mounting lugs 2.1 carry at least 80% or at least 90% or at least 95% (or even more) of the total mechanical forces and vibrations arising at the mounting locations of the mounting lugs secured to the support structure(s), or in other words the transition portions 1.1.2 transmit at most 20% or at most 10% or at most 5% (or even less) of the total mechanical forces and vibrations. Another way to consider this, is that at each mounting location, the mounting lug 2.1 carries at least 90% or at least 95% (or even more) of any bending force acting on the combination of the mounting lug 2.1 and the grounding tab 1.1, as exerted by the support structure 6 relative to the housing at the respective mounting location.

The isolation of forces is also improved because the overall metal part 1 is quite thin, as described above. But to ensure that the metal part 1 and especially its main body or lid panel 1.3 is nonetheless sufficiently self-stable in a generally flat planar configuration, and does not sag, bend or vibrate excessively, the main body 1.3 is provided with stiffening ribs 1.4. The stiffening ribs 1.4 only provide sufficient stiffness to make the metal lid flat and self-supporting, and do not provide sufficient mechanical strength for taking on a mechanical supporting function of the entire housing or the circuit board. Also in this regard, to stiffen the thin main body 1.3 of the metal part 1, it is formed with a slightly tub-shaped configuration in which a preferably continuous perimeter rim or wall 1.5 protrudes upwardly from the lid panel or main body 1.3. In FIGS. 5A and 5B it can be seen that the transition portion 1.1.2 and especially the bent portion 1.1.3 of a grounding tab 1.1 may extend outwardly from this encircling perimeter rim 1.5, or from one of the depressions 1.2. Thereby, the perimeter rim 1.5 may form or include or adjoin one or more of the bends of the bent portion 1.1.3 of the transition portion 1.1.2 of the grounding tab 1.1. Also, the perimeter rim 1.5 extends inwardly around each depression 1.2, whereby the depression 1.2 adjoins and extends to the outer perimeter of the main body or lid panel 1.3 of the metal part 1. Thereby, the depressions 1.2 represent stable securing locations for securing the metal cover 1 onto the plastic projections 2.3 inside the plastic housing part 2, despite the very thin material of the main body or lid panel 1.3 of the metal cover part 1. The fixing or securing locations of the circuit board 7 onto the plastic projections 2.3 within the plastic housing part 2 are also, for example, provided at or adjacent to the perimeter edge of the circuit board 7. This can be seen further in FIG. 6, where the mounting holes 7.2 of the circuit board 7 are visible.

Because the metal part, i.e. the metal cover or lid 1, is quite thin and mechanically not strong, it is preferred to protect the metal lid 1 by substantially enclosing it around its perimeter by the plastic housing part 2. Namely, the metal part 1 does not protrude outwardly from or beyond the plastic housing part 2. Instead, the metal part 1 is received in a recess 2.1.2 at the open end of the plastic housing part 2, such that preferably the entire perimeter edge of the metal part 1 is surrounded and covered by a plastic perimeter rim or wall 2.1.1 of the plastic housing part 2, whereby the thin (and mechanically weak or damage-sensitive) metal part 1 is laterally covered and protected by the plastic housing part 2. This can be seen especially in FIGS. 1 and 6, and is especially pertinent for the metal grounding tabs 1.1 received and protected in the recesses 2.1.2 surrounded by perimeter rims 2.1.1 of the plastic mounting lugs 2.1 of the plastic housing part 2. Thereby the thin (and mechanically relatively weak) grounding tabs 1.1 are protected against being bent or broken off, for example during storage, handling or mounting of the electronic assembly.

Furthermore, the main body or lid panel 1.3 of the metal cover part 1 being received in the recess of the main body of the plastic housing part 2 may preferably have a guiding and/or engaging function when the metal part 1 is inserted into the open end of the plastic part 2 to close the housing. In this regard, FIG. 6 shows the plastic housing part 2 with the circuit board 7 already inserted therein, but before the insertion and securing of the metal housing part 1. To complete the assembly after the stage of FIG. 6, the metal part 1 simply needs to be inserted into the recess 2.1.2 in the open end of the plastic housing part 2, and then secured with the screws 3 through the holes 7.2 of the circuit board 7 into the plastic projections 2.3 inside the plastic housing part 2. Thus, the interior side of the main body or lid panel 1.3 of the metal part 1 directly faces and bounds the interior space or chamber within the plastic housing part 2, and the perimeter edges of the metal part 1 are surrounded by the plastic perimeter rims 2.1.1. In the embodiment of FIGS. 1 and 6, the plug connector interrupts the continuity of the perimeter rim 2.1.1 of the plastic housing part 2, but the plastic body of the plug connector may be considered to be a part of the plastic perimeter rim. In other embodiments, the plastic perimeter rim is not continuous and complete, but only partial.

Although the invention has been described with reference to specific example embodiments, it will be appreciated that it is intended to cover all modifications and equivalents within the scope of the appended claims. It should also be understood that the present disclosure includes all possible combinations of any individual features recited in any of the appended claims or in the disclosure of this application. The abstract of the disclosure does not define or limit the claimed invention, but rather merely abstracts certain features disclosed in the application.

What is claimed is:

1. An electronic assembly comprising:
a housing that comprises a plastic housing part and a metal housing part that together bound an interior space within said housing; and
an electronic component arranged in said interior space;
wherein:
said plastic housing part includes a main plastic part and a mounting flange, which protrudes outwardly from said main plastic part, and by which said housing is to be mechanically secured onto an external support structure in a mounted state of said assembly,
said metal housing part includes a main metal part and a grounding tab, which protrudes outwardly from said main metal part, and which is located between said mounting flange and the support structure and is electrically connected to the support structure in the mounted state of said assembly,
an electrical ground contact of said electronic component is electrically connected with said main metal part in said interior space,
said grounding tab includes a connection portion that is to be electrically connected to the support structure in the mounted state, and a transition portion that connects the connection portion with the main metal part, and
said grounding tab has at least one of the following features:
a first feature wherein said transition portion has at least one bend,
a second feature wherein said transition portion has a width less than a width of said connection portion,
a third feature wherein said transition portion has a thickness less than a thickness of said connection portion or of said main metal part,
a fourth feature wherein said transition portion has a thickness of at most 2 mm.

2. The electronic assembly according to claim 1, wherein said main plastic part is a plastic housing body that defines said interior space therein, and said main metal part is a metal housing cover that removably covers an open side of said plastic housing body to enclose said interior space on said open side.

3. The electronic assembly according to claim 2, wherein said metal housing cover has a tub-shaped configuration comprising a main bottom panel and a perimeter rim wall that protrudes upwardly from said main bottom panel along a perimeter thereof, and wherein said transition portion of said grounding tab extends outwardly from said perimeter rim wall of said metal housing cover.

4. The electronic assembly according to claim 2, wherein said metal housing cover has depressions that adjoin a perimeter thereof, said plastic housing body has plastic projections in said interior space in registration with said depressions, said electronic component comprises a circuit board with an electronic circuit element mounted thereon, said circuit board has holes therein adjacent to a perimeter thereof in registration with said plastic projections, and said assembly further comprises fasteners engaged through said holes into said plastic projections to secure said circuit board between said depressions and said plastic projections.

5. The electronic assembly according to claim 2, wherein said open side of said plastic housing body features a recess into said plastic housing body, a perimeter of said recess is bounded by a perimeter rim wall of said plastic housing body, said metal housing cover is set into said recess, and a perimeter edge of said metal housing cover is surrounded by said perimeter rim wall of said plastic housing body.

6. The electronic assembly according to claim 1, wherein said mounting flange features a recess into said mounting flange, an outer perimeter of said recess is bounded by an outer perimeter rim wall of said mounting flange, said grounding tab is set into said recess, and an outer perimeter edge of said grounding tab is surrounded by said outer perimeter rim wall of said mounting flange.

7. The electronic assembly according to claim 6, wherein said recess in said mounting flange has a depth greater than a thickness of said grounding tab.

8. The electronic assembly according to claim 1, wherein said main metal part comprises a flat panel and stiffening ribs deformed from said flat panel, wherein said stiffening ribs are configured and arranged to make said flat panel sufficiently rigid so that said flat panel is self-supporting in a flat configuration, but not sufficiently rigid to provide structural support for any other component.

9. The electronic assembly according to claim 1, wherein said metal housing part has said at least one feature selected so that said metal housing part provides no significant mechanical structural support of said assembly relative to the support structure, and so that said transition portion isolates or reduces transmission of mechanical force or vibration from said connection portion to said main metal part of said metal housing part.

10. The electronic assembly according to claim 1, wherein said grounding tab has said first feature.

11. The electronic assembly according to claim 10, wherein said at least one bend includes at least two bends.

12. The electronic assembly according to claim 11, wherein said at least two bends form a zig-zag, serpentine, Z-shaped or U-shaped configuration in a longitudinal section of said transition portion.

13. The electronic assembly according to claim 1, wherein said grounding tab has said second feature.

14. The electronic assembly according to claim 13, wherein said width of said transition portion is at most 80% of said width of said connection portion.

15. The electronic assembly according to claim 1, wherein said grounding tab has said third feature.

16. The electronic assembly according to claim 15, wherein said thickness of said transition portion is at most 80% of said thickness of said connection portion or of said main metal part.

17. The electronic assembly according to claim 1, wherein said grounding tab has said fourth feature.

18. The electronic assembly according to claim 17, wherein an entirety of said metal housing part has a maximum thickness of at most 2 mm.

19. The electronic assembly according to claim 18, wherein said maximum thickness of said metal housing part is at most 1 mm.

20. An electronic assembly comprising:
a plastic housing part comprising a plastic housing body that defines an interior space therein, and a plastic mounting flange, which protrudes outwardly from said plastic housing body, and by which said housing is to be mechanically secured onto an external support structure in a mounted state of said assembly;
a metal housing part comprising a metal housing cover that removably covers an open side of said plastic housing body to enclose said interior space on said open side, and a grounding tab, which protrudes outwardly from said metal housing cover, and which is located between said mounting flange and the support structure and is electrically connected to the support structure in the mounted state of said assembly; and
an electronic component arranged in said interior space;
wherein said plastic housing part features a recess into said plastic mounting flange and into said plastic housing body on said open side thereof, a perimeter of said recess is bounded by a perimeter rim wall of said plastic mounting flange and of said plastic housing body, said grounding tab is set into said recess in said mounting flange, said metal housing cover is set into said recess in said plastic housing body, and an outer perimeter edge of said grounding tab and of said metal housing cover is surrounded by said perimeter rim wall of said plastic mounting flange and of said plastic housing body.

21. A housing for enclosing an electronic component and to be mounted on an external support structure, wherein said housing comprises:
a plastic housing body that defines an interior space therein configured to receive the electronic component mounted therein,
a plastic mounting lug protruding outwardly from said a housing body, with a mounting hole by which said housing is to be secured to the external support structure in an installed configuration,
a metal housing cover that removably covers an open side of said plastic housing body to enclose said interior space on said open side, and
a metal grounding tab protruding outwardly from said housing cover in registration with said mounting lug to be positioned between said mounting lug and the external support structure in the installed configuration,
wherein said housing cover and said grounding tab have a thickness of at most 2 mm,
wherein said grounding tab includes a connection portion with a hole in registration with said hole of said mounting lug, and a transition portion that connects said connection portion with said housing cover,
wherein said connection portion has an exposed metal outer surface that is configured and arranged to be electrically conductively connected to the external support structure in the installed configuration, and the housing cover has an exposed metal inner surface that is configured and arranged to be electrically conductively connected to a ground conductor of the electronic component in said interior space, and
wherein said transition portion has a reduced width compared to said connection portion, and/or said transition portion has at least one out-of-plane bend, whereby said reduced width and/or said bend serve to reduce a strength or stiffness of said grounding tab.
